(19) United States
(12) Patent Application Publication
(10) Pub. No.: US 2025/0351262 A1
(43) Pub. Date: Nov. 13, 2025

(54) CARRIER STRUCTURE AND ELECTRONIC PACKAGE HAVING THE SAME

(71) Applicant: SILICONWARE PRECISION INDUSTRIES CO., LTD., Taichung City (TW)

(72) Inventors: Tsung-Li LIN, Taichung City (TW); Chun-Lin TSAI, Taichung City (TW); Wei-Yi HUANG, Taichung City (TW)

(21) Appl. No.: 18/904,303

(22) Filed: Oct. 2, 2024

(30) Foreign Application Priority Data
May 13, 2024 (TW) 113117605

(51) Int. Cl. H05K 1/02

(52) U.S. Cl. CPC H05K 1/0227; H05K 1/0271; H05K 2201/0723; H05K 2201/0753; H05K 2201/09236; H05K 2201/093; H05K 2201/096; H05K 2201/09618; H05K 2201/09827; H05K 2201/09854

(57) ABSTRACT

A carrier structure is provided and includes: a lower shielding layer including lower shielding areas and a first separation lane; a circuit layer including conductive traces, a grounding block, and second separation lanes whose locations do not correspond to the location of the first separation lane; an upper shielding layer including upper shielding areas and a third separation lane whose location does not correspond to the locations of the second separation lanes; and at least two insulation layers with a plurality of conductive vias formed therein. Therefore, the edges of the separation lanes in the layers of the carrier structure and the electronic package having the same do not correspond to each other in the vertical direction to form structural weakness, thereby preventing cracks from occurring to the outer protective layer or even the entire carrier structure, such that the reliability of the product can be improved.

### CROSS-REFERENCE TO RELATED APPLICATIONS

The present application is based upon and claims the right of priority to TW Patent Application No. 113117605, filed May 13, 2024, the disclosure of which is hereby incorporated by reference herein in its entirety for all purposes.

### BACKGROUND

### 1. Technical Field

The present disclosure relates to a carrier structure, and more particularly, to a carrier structure used in semiconductors and an electronic package having the carrier structure.

### 2. Description of Related Art

In today's era where life is full of electronic products and technologies, circuit boards are used in almost all types of electronic systems. The range of applications for these circuit boards covers all kinds of usages from low performance, low operating frequencies to high performance, high operating frequencies. As electronic products have more and more functions and increasingly faster processing speeds, the circuits of the electronic products are gradually developing towards higher operating frequencies.

Under the requirements of high-frequency operation, the designing and manufacturing of circuit boards have become increasingly difficult and expensive. Especially today's circuit boards often have a multi-layer structure, so the signals from the same or different circuit layers inside the circuit board, or the electromagnetic interferences (referred to as EMI) such as noises from the outside of the circuit board, will have a great impact on the signals running in the circuits operating at high frequencies. Therefore, the industry has set up multiple shielding layers at intervals in the multi-layer circuit boards, such that the shielding layers can be used to shield against electromagnetic interference from the outside of the circuit board and from the internal circuits of each layer, and can also be used for grounding.

As shown in FIG. 1, a conventional circuit board 1 of a multi-layer structure includes a plurality of grounding layers 10 made of metal, and a circuit layer 11 formed with circuits is sandwiched between the grounding layers 10. The circuit layer 11 includes a plurality of conductive lines 111 used to form circuits, grounding blocks 112, a separation lane 103 between the adjacent grounding blocks 112, and a separation lane 103′ between the conductive line 111 and the adjacent conductive line 111 or grounding block 112. Although setting the multiple grounding layers 10 can achieve the purpose of shielding against electromagnetic interference, but in order to take into account both the shielding and grounding effects, each of the grounding layers 10 is generally divided into only a few large-area grounding planes 101 that are extremely close to each other, so that a protective layer 12 made of solder-resist material (e.g., green solder mask) and covering the outermost grounding plane 101 forms a depression Dp (e.g., a dimple) above the separation lane 103 between the grounding planes 101. The edges of the grounding planes 101 in different grounding layers 10 often correspond to and are aligned with each other in the vertical direction, such that the depression Dp of the protective layer 12 is stacked with the separation lanes 103 between the grounding planes 101 below in the vertical direction, resulting in that the location of the depression Dp of the protective layer 12 on the surface of the circuit board 1 and the corresponding locations of the separation lanes 103 below the depression Dp become structural weaknesses with low strength in the overall structure, causing stress to easily concentrate at the locations of the depression Dp and the separation lanes 103, so that the protective layer 12 and even the entire circuit board 1 are prone to have cracks at these locations, thereby reducing the reliability of the product using the circuit board 1.

Therefore, how to overcome the above-mentioned problems of the prior art has become an urgent issue to be solved.

### SUMMARY

In view of the aforementioned shortcomings of the prior art, the present disclosure provides a carrier structure, which comprises: a lower shielding layer comprising a plurality of lower shielding areas and a first separation lane separating the plurality of lower shielding areas; a circuit layer located above the lower shielding layer and comprising a plurality of conductive traces, at least one grounding block and a plurality of second separation lanes located between the plurality of conductive traces and the at least one grounding block, wherein a location of any one of the second separation lanes does not correspond to a location of the first separation lane; an upper shielding layer located above the circuit layer and comprising a plurality of upper shielding areas and a third separation lane located between the plurality of upper shielding areas, wherein a location of the third separation lane does not correspond to the location of any one of the second separation lanes; and at least two insulation layers formed between the lower shielding layer and the circuit layer, and between the circuit layer and the upper shielding layer respectively, wherein each of the insulation layers is formed with a plurality of conductive vias therein.

The present disclosure further provides an electronic package having the carrier structure, the electronic package comprises: the aforementioned carrier structure; and at least one electronic component disposed on and electrically connected to the carrier structure.

In the aforementioned carrier structure and electronic package, the location of the third separation lane does not correspond to the location of the first separation lane.

In the aforementioned carrier structure and electronic package, edges of the first separation lane are straight, tooth-shaped, jagged, or curved.

In the aforementioned carrier structure and electronic package, edges of each of the second separation lanes are straight, tooth-shaped, jagged, or curved.

In the aforementioned carrier structure and electronic package, edges of the third separation lane are straight, tooth-shaped, jagged, or curved.

It can be seen from the above, in the carrier structure and the electronic package having the carrier structure of the present disclosure, the location of any one of the second separation lanes located between the plurality of conductive traces and the grounding block in the circuit layer does not correspond to both the location of the first separation lane between the plurality of lower shielding areas below and the location of the third separation lane between the plurality of upper shielding areas above in the vertical direction, so that the structural weakness formed by the vertical corresponding and stacking of the parts without metals in different layers can be prevented. Therefore, the strength of the entire carrier structure and the entire electronic package having the carrier structure can be improved, thereby preventing cracks from occurring to the carrier structure and/or the protective layer formed thereon, such that the reliability of the carrier structure and the electronic package having the carrier structure can be improved.

### BRIEF DESCRIPTION OF THE DRAWINGS

FIG. 1 is a schematic view of the structure of a conventional multi-layer circuit board.

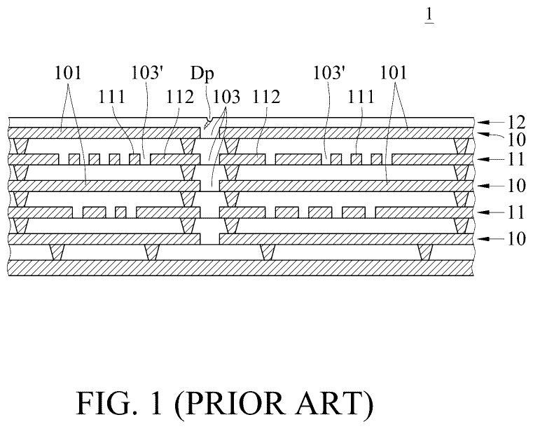

FIG. 2A is a schematic partial cross-sectional view of an embodiment of a carrier structure of the present disclosure.

FIG. 2B to FIG. 2D are schematic partial top views of a lower shielding layer, a circuit layer and an upper shielding layer in FIG. 2A respectively.

FIG. 2E to FIG. 2G are schematic partial top views of different variant aspects of separation lanes in embodiments of the present disclosure.

FIG. 3 is a schematic partial cross-sectional view of an embodiment of an electronic package of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “above,” “on,” “first,” “second,” “third,” “a,” “one,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

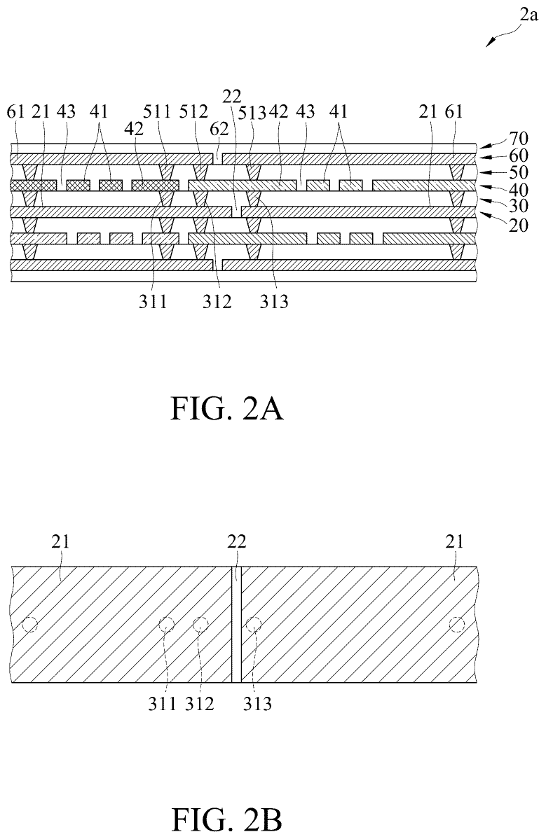

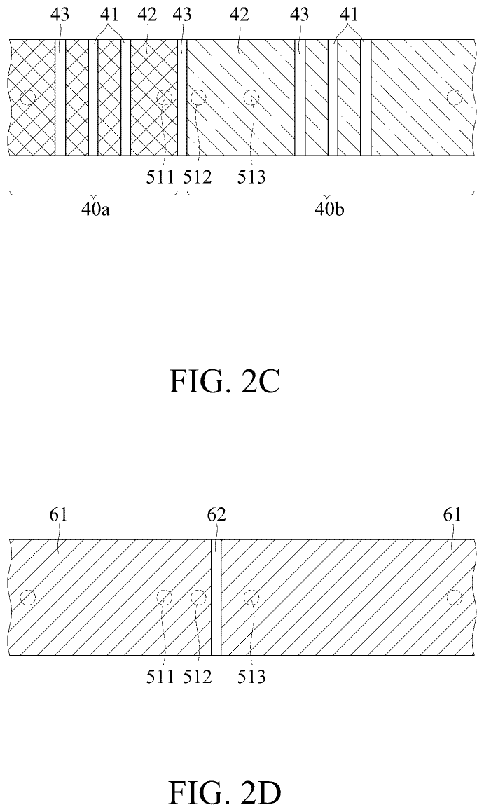

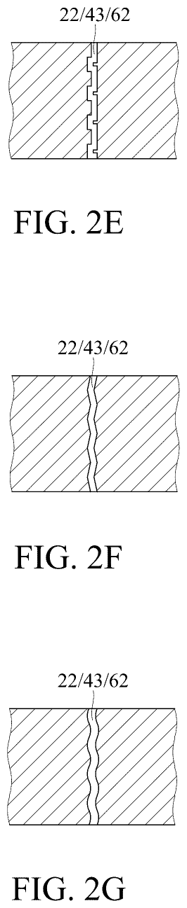

FIG. 2A to FIG. 2G are schematic views of an embodiment of a carrier structure 2a of the present disclosure.

As shown in FIG. 2A, in an embodiment, the carrier structure 2a comprises: a lower shielding layer 20, a circuit layer 40 located above the lower shielding layer 20, an upper shielding layer 60 located above the circuit layer 40, an insulation layer 30 formed between the lower shielding layer 20 and the circuit layer 40, and an insulation layer 50 formed between the circuit layer 40 and the upper shielding layer 60.

Please also refer to FIG. 2B. The lower shielding layer 20 comprises a plurality of lower shielding areas 21 and a first separation lane 22 that separates the plurality of lower shielding areas 21. The lower shielding areas 21 are generally made of metal such as copper, and the lower shielding areas 21 function as shields against the electromagnetic interference beneath and can be served as grounding planes.

Please refer to FIG. 2C also. The circuit layer 40 comprises a plurality of conductive traces 41, at least one grounding block 42, and a plurality of second separation lanes 43 located between the plurality of conductive traces 41 and the at least one grounding block 42. The plurality of conductive traces 41 are conductive wires that constitute the circuit. Like the grounding block 42, the plurality of conductive traces 41 are generally foils or films made of metal such as copper. The location of any one of the second separation lanes 43 located between the plurality of conductive traces 41 and the grounding block 42 does not correspond to the location of the first separation lane 22 located in the lower shielding layer 20 below. In other words, the edge of each of the conductive traces 41 and the edge of the grounding block 42 in the circuit layer 40 and the edge of each of the lower shielding areas 21 in the lower shielding layer 20 also do not correspond to each other in the vertical direction.

In practical applications, as an example, the circuits in the circuit layer 40 are generally divided into several areas according to different functions or characteristics, such as a signal processing area and a power area. In an embodiment, the circuits in the circuit layer 40 are divided into two areas, namely a first circuit portion 40a and a second circuit portion 40b. The circuits in the circuit layer 40 can be divided into more areas and are not limited to the example shown here. No matter how many areas that the circuit layer 40 is divided into, and regardless of the differences between the functions of these areas, the entire circuit layer 40 is usually still formed in the same process step.

The insulation layer 30 is formed between the lower shielding layer 20 and the circuit layer 40. The insulation layer 30 is made of polybenzoxazole (PBO), polyimide (PI), prepreg (PP), or any other suitable material, and the present disclosure is not limited to as such. In addition, a plurality of conductive vias 311, 312, 313 connecting the lower shielding layer 20 and the circuit layer 40 are formed in the insulation layer 30 so as to electrically connect the grounding block 42 and the lower shielding areas 21 in the lower shielding layer 20 depending on requirement.

Please refer to FIG. 2D also. The upper shielding layer 60 is located above the circuit layer 40 and comprises a plurality of upper shielding areas 61 and a third separation lane 62. The plurality of upper shielding areas 61 are used to shield against the electromagnetic interference from above and can be used for grounding as well. The third separation lane 62 is formed between the plurality of upper shielding areas 61 to divide the plurality of upper shielding areas 61, and the location of the third separation lane 62 does not correspond to the location of any one of the second separation lanes 43, i.e., the edge of each of the upper shielding areas 61 in the upper shielding layer 60 does not correspond to the edge of each of the conductive traces 41 and the edge of the grounding block 42 in the circuit layer 40 underneath in the vertical direction either. In addition, when the upper shielding layer 60 is the top layer of the carrier structure 2a, a protective layer 70 made of solder-resist material (e.g., green solder mask) may be formed on the upper shielding layer 60, thereby preventing each of the upper shielding areas 61 from being oxidized or damaged accidentally.

Similarly, the insulation layer 50 may also be formed on the circuit layer 40 and between the circuit layer 40 and the upper shielding layer 60. The insulation layer 50 may also be made of polybenzoxazole (PBO), polyimide (PI), prepreg (PP), or any other suitable material. Further, a plurality of conductive vias 511, 512, 513 connecting the circuit layer 40 and the upper shielding layer 60 may also be formed in the insulation layer 50 between the circuit layer 40 and the upper shielding layer 60 so as to electrically connect the grounding block 42 and the upper shielding areas 61 in the upper shielding layer 60 depending on requirement.

Since both the location of the first separation lane 22 in the lower shielding layer 20 and the location of the third separation lane 62 in the upper shielding layer 60 do not correspond to the location of any one of the second separation lanes 43 in the circuit layer 40 (while the location of the first separation lane 22 may or may not correspond to the location of the third separation lane 62), the structural weakness caused by stacking parts that do not have metal structures such as the conductive traces 41, the grounding blocks 42, or the shielding areas in different layers can be prevented, so that the strength of the entire carrier structure 2a can be improved, thereby preventing cracks from occurring to the carrier structure 2a and/or the protective layer 70 formed thereon.

The circuit layer 40 may be a redistribution layer (RDL), for example. Or, different kinds of active or passive components (not shown) may be disposed in the circuit layer 40. When one end of each of the active or passive components needs to be grounded, the grounding blocks 42 of the circuit layer 40 can be used for grounding, so that the flexibility of component configuration in the circuit layer 40 can be improved.

In addition to both the location of the first separation lane 22 in the lower shielding layer 20 and the location of the third separation lane 62 in the upper shielding layer 60 do not correspond to the location of any one of the second separation lanes 43 in the circuit layer 40 as mentioned above, in some preferred aspects of embodiments, the location of the third separation lane 62 in the upper shielding layer 60 and the location of the first separation lane 22 in the lower shielding layer 20 also do not correspond to each other. Thus, the separation lanes in different layers that are not adjacent to each other do not correspond to each other in the vertical direction, such that the strength of the entire carrier structure 2a can be further improved.

In some embodiments, each of the edges of the first separation lane 22 may be straight. Similarly, each of the edges of each of the second separation lanes 43 and/or each of the edges of the third separation lane 62 may also be straight. Or, as shown in FIG. 2E to FIG. 2G, in some variant aspects of embodiments, depending on the requirements of the circuit configuration, each of the edges of the first separation lane 22, the second separation lanes 43 and the third separation lane 62 may also be tooth-shaped, jagged, curved, or may have any other suitable shapes, and the present disclosure is not limited to as such.

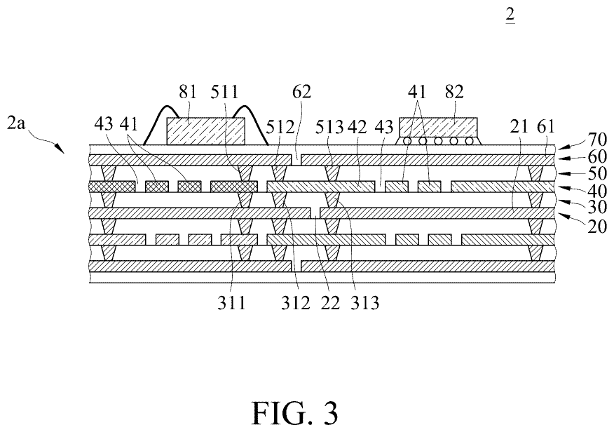

In an embodiment, an electronic package 2 having the carrier structure 2a is also provided. As shown in FIG. 3, the electronic package 2 comprises: the carrier structure 2a, and two electronic components 81, 82 disposed on the carrier structure 2a and electrically connected to the carrier structure 2a. Although the two electronic components 81, 82 are disposed on the carrier structure 2a as an example in the embodiment, but depending on the design, there can also be only one electronic component or multiple electronic components disposed, and the electronic components 81, 82 may be disposed on the carrier structure 2a by the method such as wire bonding, flip-chip, etc., and the present disclosure is not limited to as such. The electronic components 81, 82 may be active components such as central processing units, graphics processing units, etc., or passive components such as resistors, capacitors, or inductors, etc., or a combination of active components and passive components. Any electronic components can be used as the electronic components 81, 82 as long as they can meet the requirements of the design of the circuit, and the present disclosure is not limited to as such.

In summary, in the carrier structure 2a and the electronic package 2 having the carrier structure 2a of the present disclosure, the location of any one of the second separation lanes 43 located between the plurality of conductive traces 41 and the grounding block 42 in the circuit layer 40 does not correspond to both the location of the first separation lane 22 between the plurality of lower shielding areas 21 below and the location of the third separation lane 62 between the plurality of upper shielding areas 61 above in the vertical direction (while the location of the first separation lane 22 and the location of the third separation lane 62 may or may not correspond to each other), so that the structural weakness formed by the vertical corresponding and stacking of the parts without metals in different layers can be prevented. Therefore, the strength of the entire carrier structure 2a and the entire electronic package 2 having the carrier structure 2a can be improved, thereby preventing cracks from occurring to the carrier structure 2a and/or the protective layer 70 formed thereon, such that the reliability of the carrier structure 2a and the electronic package 2 having the carrier structure 2a can be improved.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A carrier structure, comprising:
a lower shielding layer comprising a plurality of lower shielding areas and a first separation lane separating the plurality of lower shielding areas;
a circuit layer located above the lower shielding layer and comprising a plurality of conductive traces, at least one grounding block and a plurality of second separation lanes located between the plurality of conductive traces and the at least one grounding block, wherein a location of any one of the second separation lanes does not correspond to a location of the first separation lane;
an upper shielding layer located above the circuit layer and comprising a plurality of upper shielding areas and a third separation lane located between the plurality of upper shielding areas, wherein a location of the third separation lane does not correspond to the location of any one of the second separation lanes; and
at least two insulation layers formed between the lower shielding layer and the circuit layer, and between the circuit layer and the upper shielding layer respectively, wherein each of the insulation layers is formed with a plurality of conductive vias therein.

2. The carrier structure of claim 1, wherein the location of the third separation lane does not correspond to the location of the first separation lane.

3. The carrier structure of claim 1, wherein edges of the first separation lane are straight, tooth-shaped, jagged, or curved.

4. The carrier structure of claim 1, wherein edges of each of the second separation lanes are straight, tooth-shaped, jagged, or curved.

5. The carrier structure of claim 1, wherein edges of the third separation lane are straight, tooth-shaped, jagged, or curved.

6. An electronic package, comprising:
a carrier structure, comprising:
a lower shielding layer comprising a plurality of lower shielding areas and a first separation lane separating the plurality of lower shielding areas;
a circuit layer located above the lower shielding layer and comprising a plurality of conductive traces, at least one grounding block and a plurality of second separation lanes located between the plurality of conductive traces and the at least one grounding block, wherein a location of any one of the second separation lanes does not correspond to a location of the first separation lane;
an upper shielding layer located above the circuit layer and comprising a plurality of upper shielding areas and a third separation lane located between the plurality of upper shielding areas, wherein a location of the third separation lane does not correspond to the location of any one of the second separation lanes; and
at least two insulation layers formed between the lower shielding layer and the circuit layer, and between the circuit layer and the upper shielding layer respectively, wherein each of the insulation layers is formed with a plurality of conductive vias therein; and
at least one electronic component disposed on and electrically connected to the carrier structure.

7. The electronic package of claim 6, wherein the location of the third separation lane does not correspond to the location of the first separation lane.

8. The electronic package of claim 6, wherein edges of the first separation lane are straight, tooth-shaped, jagged, or curved.

9. The electronic package of claim 6, wherein edges of each of the second separation lanes are straight, tooth-shaped, jagged, or curved.

10. The electronic package of claim 6, wherein edges of the third separation lane are straight, tooth-shaped, jagged, or curved.
